(19) United States
(12) Patent Application Publication
(10) Pub. No.: US 2026/0343728 A1
(43) Pub. Date: Oct. 29, 2026

(54) HYBRID PRINTED CIRCUIT BOARD WITH EMBEDDED OPTICAL SIGNAL LAYER

(71) Applicant: Toyota Motor Engineering & Manufacturing North America, Inc., Plano, TX (US)

(72) Inventors: Ercan Mehmet Dede, Ann Arbor, MI (US); Paul Donald Schmalenberg, Ann Arbor, MI (US); Shailesh N. Joshi, Ann Arbor, MI (US)

(73) Assignees: Toyota Motor Engineering & Manufacturing North America, Inc., Plano, TX (US); Toyota Jidosha Kabushiki Kaisha, Toyota-shi Aichi-ken (JP)

(21) Appl. No.: 19/192,647

(22) Filed: Apr. 29, 2025

(51) Int. Cl. H05K 1/02; G01N 21/64; H01F 27/28

(52) U.S. Cl. CPC H05K 1/0274; G01N 21/64; H01F 27/2823; H05K 1/0206; G01N 2201/0612; G01N 2201/08; H05K 2201/064; H05K 2201/08; H05K 2201/10098; H05K 2201/10121; H05K 2201/10151

(57) ABSTRACT

Disclosed herein are examples of circuit boards that have optical signal layers. In one example, a hybrid printed circuit board includes an optical signal layer embedded within the hybrid printed circuit board that is configured to propagate optical signals from a light source. This optical signal layer includes an optical waveguide that directs the optical signals to a light-sensitive component or a quantum material located within the hybrid printed circuit board.

### TECHNICAL FIELD

The subject matter described herein relates, in general, to circuit boards and, more specifically, to hybrid printed circuit boards with embedded optical signal layers.

### BACKGROUND

The background description provided is to present the context of the disclosure generally. Work of the inventor, to the extent it may be described in this background section, and aspects of the description that may not otherwise qualify as prior art at the time of filing, are neither expressly nor impliedly admitted as prior art against the present technology.

In some electronic systems, particularly those including high-power modules, processors, and sensors, sophisticated management of thermal and electrical performance is required. Advanced system challenges may arise when conventional printed circuit board constructions rely on standard dielectric substrates transmitting purely electrical signals. Such substrates often may not efficiently dissipate heat or manage rapid temperature shifts and may not transmit/acquire control signals with sufficient noise isolation or speed. As a result, these systems further contend with issues related to electromagnetic interference and the integration of advanced sensing capabilities, which are crucial for real-time performance monitoring. In some instances, designers have resorted to using external sensor attachments or separate circuitry or optical devices, thereby adding complexity and introducing potential points of failure. Once these challenges are recognized, achieving precise control over such operational parameters becomes complicated by limitations in traditional printed circuit board materials and configurations, leading to iterative adjustments as well as considerable trial and error to optimize both electrical and thermal performance under varied conditions.

### SUMMARY

This section generally summarizes the disclosure and is not a comprehensive explanation of its full scope or all of its features.

In one embodiment, a hybrid printed circuit board includes an optical signal layer embedded within the board. The optical signal layer may include an optical waveguide that directs the optical signals to either a light-sensitive component or a quantum material located within the hybrid printed circuit board.

In another embodiment, an optical signal layer includes an optical waveguide configured to propagate optical signals from a light source. The optical signal layer is configured to be located above, below, or between electronic signal layers of a hybrid printed circuit board.

Further areas of applicability and various methods of enhancing the disclosed technology will become apparent from the description provided. The description and specific examples in this summary are intended for illustration only and are not intended to limit the scope of the present disclosure.

### BRIEF DESCRIPTION OF THE DRAWINGS

The accompanying drawings, which are incorporated in and constitute a part of the specification, illustrate various systems, methods, and other embodiments of the disclosure. It will be appreciated that the illustrated element boundaries (e.g., boxes, groups of boxes, or other shapes) in the figures represent one embodiment of the boundaries. In some embodiments, one element may be designed as multiple elements, or multiple elements may be designed as one element. In some embodiments, an element shown as an internal component of another element may be implemented as an external component and vice versa. Furthermore, elements may not be drawn to scale.

FIG. 1 illustrates a cut-away perspective view of a hybrid printed circuit board, including optical signal layers embedded within a multilayer substrate.

FIGS. 2 and 3 illustrate an embedded Helmholtz coil formed using in-plane conductive traces and through-plane vias integrated into the hybrid printed circuit board shown in FIG. 1.

FIG. 4 illustrates a control system incorporating a machine learning model trained on data generated from the hybrid printed circuit board of FIG. 1.

### DETAILED DESCRIPTION

Described herein is a hybrid printed circuit board. Moreover, the hybrid printed circuit board may include traditional electronic signal layers made out of FR-4 or other suitable material and may be opaque. Like traditional circuit boards, the hybrid printed circuit board may include one or more electrically conductive traces deposited on these electronic signal layers and vias that form electrical connections between the conductive traces found on different layers.

In addition, the hybrid circuit board also includes one or more optical signal layers embedded within the hybrid circuit board. The optical signal layers can include waveguides that function to transport optical signals from a source to a light-sensitive component. While the light-sensitive component can vary from application to application, in one example, the light-sensitive component could be an optically switched gate driver. In another example, the light-sensitive component could be quantum material that emits fluorescence that changes in response to excitation by light in combination with magnetic fields, temperature, and strain, enabling precise sensing through optically detected magnetic resonance (ODMR). Other components may also be found within the hybrid circuit board, including a Helmholtz coil that is constructed using in-plane traces and through-plane vias of the hybrid circuit board.

Further still, a control system may be in communication with one or more components of the hybrid printed circuit board to analyze fluorescence data from the quantum material to determine environmental conditions such as magnetic field strength, direction, temperature, and strain. Moreover, the control system may utilize a machine learning model that may be trained on data generated from the hybrid printed circuit board to learn how different Helmholtz coil activations affect the quantum response, enabling accurate interpretation of complex sensor signals. This allows for real-time monitoring, calibration, and predictive diagnostics tailored to the specific board configuration of the hybrid printed circuit board.

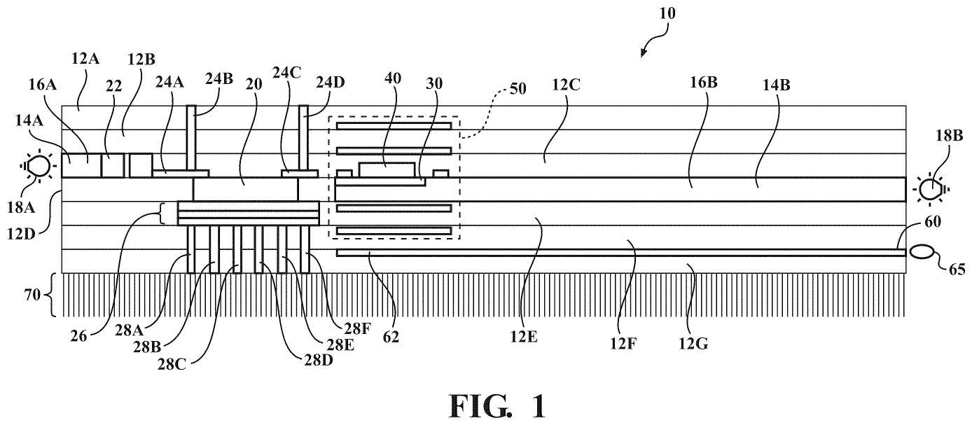

Referring to FIG. 1, illustrated is one example of a hybrid printed circuit board 10. The hybrid printed circuit board 10 may include several electrical signal layers 12A-12G, which may be FR-4 or similar layers. These electrical signal layers serve as the structural and electrical foundation of the system. As is known, FR-4 is a flame-retardant, glass-reinforced epoxy laminate material that provides mechanical stability, electrical insulation, and thermal resistance. The electrical signal layers 12A-12G support traditional circuit board functions, including routing of electrical signals, distribution of power and ground planes, routing of microwave antenna, and mechanical mounting of components. Accordingly, the electrical signal layers 12A-12G may include conductive traces that extend across each layer and through-plane vias that electrically connect traces between layers, depending on the application.

The hybrid printed circuit board 10 may include one or more optical signal layers 14A-14B embedded within the hybrid printed circuit board 10. As one such example, the one or more optical signal layers 14A-14B may be disposed between one or more of the electrical signal layers 12A-12G. As such, the optical signal layers 14A-14B form part of the overall dielectric structure of the hybrid printed circuit board 10, enabling optical signal routing, quantum material support, and embedded sensing functionality without disrupting the electrical continuity of the surrounding electrical signal layers 12A-12G. The optical signal layers 14A-14B may be configured to provide structural support to the hybrid printed circuit board 10 while maintaining optical clarity for signal propagation.

As a non-limiting example, the optical signal layers 14A-14B may be formed from a functionalized glass material, such as alkali aluminosilicate glass or borosilicate glass, and serve as both a dielectric insulator and a platform for optical and quantum functionality. Each optical signal layer 14A-14B may be positioned above, below, or between selected electrical signal layers 12A-12G and may be laminated into the hybrid printed circuit board 10 using high-temperature or adhesive-based bonding methods compatible with hybrid printed circuit board fabrication. The optical signal layers 14A-14B may include embedded optical waveguides 16A-16B, respectively, formed by laser writing or ion-exchange processes for routing optical signals to and from integrated sensing regions. As will be explained later, in some examples, the optical signal layers 14A-14B also support quantum materials 30 (e.g., nano-diamonds with nitrogen-vacancy centers, hexagonal boron nitride flakes with boron vacancies, and silicon carbide particles containing divacancies or silicon-vacancy defects) and provide a stable medium for laser excitation, microwave interaction, and fluorescence detection.

As mentioned, the optical signal layers 14A-14B, along with the optical waveguides 16A-16B, allow for optical communication between a light source, such as light sources 18A and 18B, and a light-sensitive component. In one example, the hybrid printed circuit board 10 may include a component 20 (or more than one component) supported either on or within the hybrid printed circuit board 10. In some cases, component 20 may be embedded within the electrical signal layers 12A-12G. Alternatively, component 20 may be located on an exposed top or bottom surface of the hybrid printed circuit board 10. The type of component 20 may vary depending on the application. In one example, component 20 can be an ultra-wide bandgap (UWBG) device, which may be a type of semiconductor power device made from materials with a bandgap significantly wider than traditional silicon (Si) and even wider than wide bandgap materials like silicon carbide (SiC) and gallium nitride (GaN). However, it should be understood that component 20 can take any one of a number of forms and could alternatively be a central processing unit (CPU), graphics processing unit (GPU), or any other active/passive electrical component capable of being supported by the hybrid printed circuit board 10.

The component 20 may be switched on utilizing an optically switched gate driver 22 that is in optical communication with the optical waveguide 16A of the optical signal layer 14A. In addition, the optically switched gate driver 22 is in electrical communication with the component 20 via an electrically conductive trace 24A printed on the electrical signal layer 12C. It is also noted that the conductive trace 24A may be connected to an electrically conductive via 24B and may further include an electrically conductive trace 24C and an electrically conductive via 24D. In operation, optical signals delivered through optical waveguide 16A from a light source 18A are received by the optically switched gate driver 22, which converts the optical input into an electrical gate signal suitable for switching the component 20 via the conductive trace 24A. The light source 18A can take any one of a number of different forms, including a fiber-coupled laser, but in one example may be a laser diode and/or a light-emitting diode (LED) integrated into the hybrid circuit board and configured to emit optical signals into the optical waveguide 16A, where the light is routed to the optically switched gate driver 22.

The hybrid printed circuit board 10 may also include a direct bonded copper (DBC) structure 26 that is in thermal communication with the one or more component 20. The DBC structure 26 may be a multilayer structure that includes a ceramic insulating layer, such as alumina or aluminum nitride, with copper layers bonded directly onto one or both sides of the ceramic layer. In one example, the component 20 may be soldered or bonded directly onto a copper layer of the DBC structure 26. This copper layer acts as both an electrical conductor and a thermal path. The ceramic layer provides electrical insulation between the top copper layer and a second copper layer located on the opposite side of the structure while still allowing heat to pass efficiently through the plane. In addition, thermal vias 28A-28F extend through electrical signal layers 12F and 12G and are thermally connected to the DBC structure 26 and a cold plate 70 so as to cool the component 20. Moreover, in this example, the DBC structure 26 handles local heat extraction from the component 20, while the cold plate 70 handles heat removal from the full hybrid printed circuit board 10. There additionally may be a very thin thermally conductive electrical insulation layer (not shown) at the interface between the cold plate 70 and the hybrid printed circuit board 10.

As opposed to using conductive traces and vias to switch the component 20 on or off, the use of an optically switched gate driver 22 in conjunction with the optical signal layer 14A to control the activation of the component 20 provides galvanic isolation between the control circuitry and the component 20. This isolation helps reduce the risk of ground loop interference, voltage spikes, and electrical noise coupling. Additionally, optical signal paths within the optical signal layer 14A are inherently immune to electromagnetic interference (EMI) and do not introduce parasitic inductance or signal crosstalk, as is common with traditional high-speed electrical traces. As a result, this approach enhances signal integrity, improves switching reliability, and is particularly well-suited for the high-frequency, high-voltage operation typical of high-speed components.

As mentioned before, quantum materials can also be utilized within the hybrid printed circuit board 10. Moreover, the hybrid printed circuit board 10 includes an optical signal layer 14B that contains one or more optical waveguides 16B for transmitting optical signals from a light source 18B to a light-sensitive component—specifically, a quantum material 30. Similar to the light source 18A, the light source 18B can take various forms, such as a fiber-coupled laser, heterogeneously integrated laser diode, or an LED. In one example, the light source 18B is configured to emit optical signals into the optical waveguide 16B, which routes the light to the quantum material 30.

The quantum material 30 comprises functionalized particles, such as nano-diamonds, hexagonal boron nitride (hBN) flakes, or silicon carbide (SiC) particles, engineered to include optically active defects known as color centers. These color centers emit light in response to external stimuli, including temperature changes, mechanical strain, magnetic fields, or optical excitation. Within the hybrid printed circuit board 10, the quantum material 30 is embedded in or applied to one or more transparent glass layers, such as optical signal layer 14B, in proximity to an optical waveguide 16B. The waveguide directs excitation light from a light source 18B to the quantum material 30, stimulating emission. In one example, the response of the quantum material 30 when excited by the light source 18B may be based on an operating condition of the component 20. The quantum material 30 may be further baffled in a light-tight cavity (not shown) to only receive light from the optical waveguide 16B.

Light emitted from the quantum material can be captured by a detector 40 that is optically coupled to the optical waveguide 16B and the aforementioned light-tight cavity. The detector 40 converts the received optical signals into electrical signals that can be processed by a data acquisition system, which will be described later in this disclosure, to determine parameters such as temperature, strain, or electromagnetic field strength at the location of the quantum material 30. This configuration enables real-time, localized state variable field sensing within the hybrid printed circuit board 10, enhancing diagnostic capabilities and improving the reliability and safety of high-performance electronic systems.

The detector 40 may be an optical sensor configured to receive light emitted from the quantum material 30 in response to external stimuli. As such, the detector 40 may be a photodiode, avalanche photodiode (APD), or other semiconductor-based photodetector capable of detecting low-intensity light across a defined wavelength range associated with the color center emissions. The detector 40 is positioned (heterogeneously integrated) within the hybrid printed circuit board 10 so as to receive emissions from the quantum material 30. Upon receiving the optical signals, the detector 40 converts them into electrical signals that are processed by downstream electronics to determine localized conditions such as temperature, strain, or magnetic field intensity. In some embodiments, the detector 40 may be embedded within the hybrid printed circuit board 10, as shown, or alternatively mounted on a surface layer, such as the electrical signal layer 12A.

The hybrid printed circuit board 10 may also include Helmholtz coils 50 embedded within the hybrid printed circuit board 10. The Helmholtz coils 50 are constructed utilizing electrically conductive traces across different electrical signal layers 12B-12E as well as electrical vias connecting these conductive traces across different layers. The Helmholtz coils 50 are configured to generate a uniform magnetic field within a localized region surrounding the quantum material 30 of the hybrid printed circuit board 10. This magnetic field is used to stimulate the quantum material 30, specifically targeting magnetic field-sensitive color centers that respond optically to changes in the surrounding magnetic environment. The presence of the coil enables quantum sensing functions such as magnetometry or magnetic-field-based temperature compensation by providing a known reference or excitation field. Incorporating the coil directly into the hybrid printed circuit board 10 allows for compact integration and precise spatial alignment with the quantum material 30.

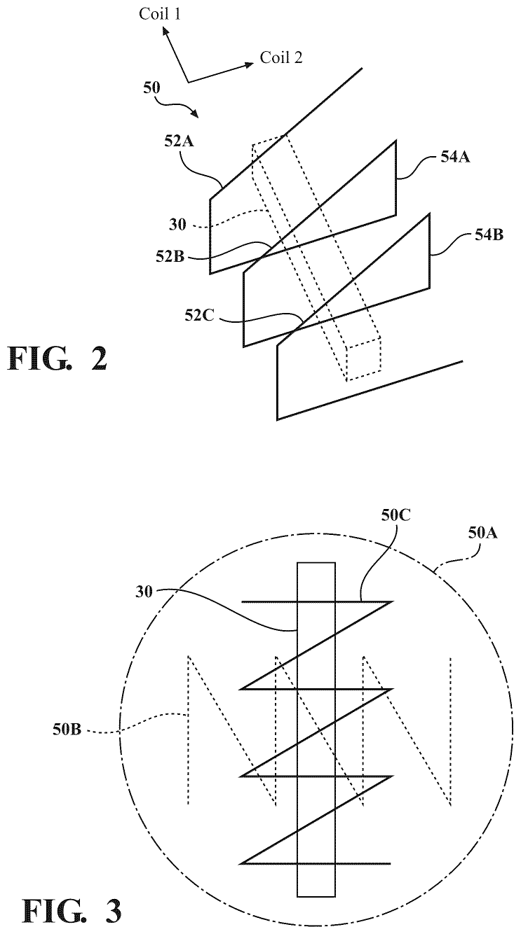

Referring to the perspective view in FIG. 2, illustrated is a more detailed schematic of the Helmholtz coils 50. In this example, the Helmholtz coils 50 are arranged around the quantum material 30, which is coupled to the optical waveguide 16B. The coil can include portions formed by electrically conductive traces 52A-52C on different electrical signal layers of the hybrid printed circuit board 10, such as electrical signal layers 12A-12G. These conductive traces 52A-52C are electrically connected to one another by electrical vias 54A and 54B. For instance, the via 54A connects conductive trace 52A to conductive trace 52B, while the via 54B connects conductive trace 52B to conductive trace 52C. By alternating the routing direction on successive layers and connecting them across layers with vias, a compact and efficient coil structure can be embedded within the PCB. The trace width, spacing, and number of turns may be selected based on the desired magnetic field strength and uniformity at the target location, which in this embodiment is near the quantum material 30. This process may be repeated across multiple layers, depending on the number of coil windings required for a given magnetic field specification.

As shown in FIG. 3, the Helmholtz coils 50 may include multiple coil sets, such as coils 50A-50C, arranged in orthogonal or otherwise strategic orientations around the quantum material 30. This multi-coil configuration enables the generation of controlled magnetic fields along different axes, which can be useful for vector magnetic field measurements or calibration of quantum material responses.

Returning to FIG. 1, the hybrid printed circuit board 10 may also include a microwave antenna 60 embedded within the hybrid printed circuit board 10. In this example, the microwave antenna 60 is a conductive trace deposited on the electrical signal layer 12G. The microwave antenna 60 has an end 62 that generally extends along the electrical signal layer 12G so that it is adjacent or proximate to the Helmholtz coils 50. The microwave antenna 60 may be controlled by a radiofrequency source 65. The microwave antenna 60 is configured to generate electromagnetic fields in the microwave range. It is used to excite specific spin states within the quantum material 30, particularly those with magnetic-sensitive color centers such as nitrogen-vacancy (NV) centers in diamond or similar defects in other quantum materials. These spin transitions are sensitive to external conditions like magnetic field strength and temperature, making microwave excitation useful for certain quantum sensing modalities such as optically detected magnetic resonance (ODMR).

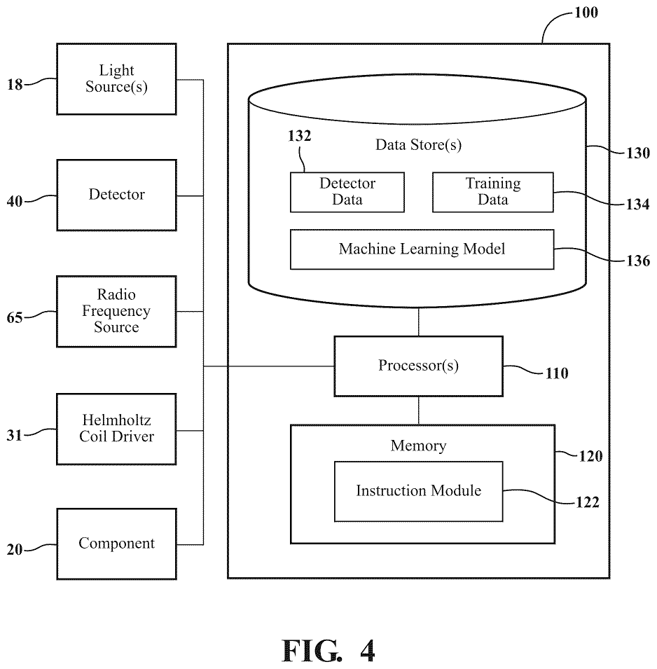

Referring to FIG. 4, illustrated is one example of a control system 100 for controlling and/or evaluating various aspects of the hybrid printed circuit board 10. As such, in this example, the control system 100 may be operatively connected to the light source(s) 18, such as the light sources 18A and/or 18B illustrated in FIG. 1, the detector 40, the radiofrequency source 65 that drives the microwave antenna 60, a Helmholtz coil driver 31 that operates the Helmholtz coils 50, and/or the component 20. Depending on the application, the control system 100 may be integrated within the hybrid printed circuit board 10 or may be separate from the hybrid printed circuit board 10, as shown.

The control system 100 may include a processor(s) 110. In one or more embodiments, the processor(s) 110 is an application-specific integrated circuit that is configured to implement functions associated with an instruction module 122. In general, the processor(s) 110 is an electronic processor, such as a microprocessor, which is capable of performing various functions as described herein. In one embodiment, the control system 100 includes a memory 120 that stores the instruction module 122. The memory 120 may be a random-access memory (RAM), read-only memory (ROM), a hard disk drive, a flash memory, or other suitable memory for storing the instruction module 122. The instruction module 122 is, for example, computer-readable instructions that, when executed by the processor(s) 110, cause the processor(s) 110 to perform the various functions disclosed herein.

Furthermore, in one embodiment, the control system 100 includes a data store(s) 130. The data store(s) 130 is, in one embodiment, an electronic data structure such as a database that is stored in the memory 120 or another memory and that is configured with routines that can be executed by the processor(s) 110 for analyzing stored data, providing stored data, organizing stored data, and so on. Thus, in one embodiment, the data store(s) 130 stores data used by the instruction module 122 in executing various functions.

In one example, the data store(s) 130 may include detector data 132 collected from the detector 40, training data 134, and a machine learning model 136. The machine learning model 136 may characterize and interpret the magnetic field patterns generated by the embedded Helmholtz coils 50 during the operation of the hybrid printed circuit board 10. Due to the 3D geometry of the Helmholtz coils 50, the resulting magnetic field may vary in intensity and direction across the region surrounding the quantum material 30. To accurately resolve the magnetic field components along different spatial axes (X, Y, and Z), the machine learning model 136 is trained on training data 134 collected from the hybrid printed circuit board 10 while different coil elements (e.g., coils 50A-50C) are selectively activated. This training process enables the machine learning model 136 to learn the correlation between coil activation patterns and the resulting magnetic field vector at the location of the quantum material 30. Once trained, the machine learning model 136 can be used in real-time to infer magnetic field strength and direction based on the detector data 132, enhancing the precision of quantum sensing measurements and allowing for adaptive control of the Helmholtz coils 50 current to maintain optimal excitation conditions.

During an inference mode, the instructions of the instruction module 122 cause the processor(s) 110 to utilize the machine learning model 136 to analyze detector data 132 generated by the detector 40 to estimate the characteristics of the magnetic field at the quantum sensing site. As different components of the Helmholtz coils 50 (e.g., coils 50A-50C) are selectively activated, the model receives corresponding output from the detector 40, such as light intensity or wavelength shifts emitted by the quantum material, and maps those signals to predicted magnetic field vectors (X, Y, Z components). This enables the control system 100 to resolve the magnitude and direction of the local magnetic field without requiring manual calibration or full physical field simulations. In some embodiments, the output from the detector 40 may be used dynamically to adjust coil currents, correct for environmental drift, remove background noise, or provide diagnostic feedback to the processor(s) 110 to better control the component 20.

It should be appreciated that any of the systems described in this specification can be configured in various arrangements with separate integrated circuits and/or chips. The circuits are connected via connection paths to provide for communicating signals between the separate circuits. Of course, while separate integrated circuits are discussed, in various embodiments, the circuits may be integrated into a common heterogeneously integrated circuit board. Additionally, the integrated circuits may be combined into fewer integrated circuits or divided into more integrated circuits. As is known in the current state of the art, an interposer may be further utilized in combination with possible 2.5D or 3D packaging techniques.

In another embodiment, the methods described and/or their equivalents may be implemented with computer-executable instructions. Thus, in one embodiment, a non-transitory computer-readable medium is configured with stored computer-executable instructions that, when executed by a machine (e.g., processor, computer, and so on), cause the machine (and/or associated components) to perform the method.

While for purposes of simplicity of explanation, the illustrated methodologies in the figures are shown and described as a series of blocks, it is to be appreciated that the order of the blocks does not limit the methodologies, as some blocks can occur in different orders and/or concurrently with other blocks from that shown and described. Moreover, less than all the illustrated blocks may be used to implement an example methodology. Blocks may be combined or separated into multiple components. Furthermore, additional and/or alternative methodologies can employ additional blocks that are not illustrated.

Detailed embodiments are disclosed herein. However, it is to be understood that the disclosed embodiments are intended only as examples. Therefore, specific structural and functional details disclosed herein are not to be interpreted as limiting but merely as a basis for the claims and as a representative basis for teaching one skilled in the art to employ various aspects herein in virtually any appropriately detailed structure. Further, the terms and phrases used herein are not intended to be limiting but rather to provide an understandable description of possible implementations.

The flowcharts and block diagrams in the figures illustrate the architecture, functionality, and operation of possible implementations of systems, methods, and computer program products according to various embodiments. In this regard, each block in the flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

The systems, components and/or processes described above can be realized in hardware or a combination of hardware and software and can be realized in a centralized fashion in one processing system or in a distributed fashion where different elements are spread across several interconnected processing systems. Any processing system or another apparatus adapted for carrying out the methods described herein is suited. A combination of hardware and software can be a processing system with computer-usable program code that, when being loaded and executed, controls the processing system such that it carries out the methods described herein. The systems, components, and/or processes also can be embedded in a computer-readable storage, such as a computer program product or other data programs storage device, readable by a machine, tangibly embodying a program of instructions executable by the machine to perform methods and processes described herein. These elements can also be embedded in an application product that comprises all the features enabling the implementation of the methods described herein and which when loaded in a processing system, is able to carry out these methods.

Furthermore, the arrangements described herein may take the form of a computer program product embodied in one or more computer-readable media having computer-readable program code embodied, e.g., stored, thereon. Any combination of one or more computer-readable media may be utilized. The computer-readable medium may be a computer-readable signal medium or a computer-readable storage medium. The phrase “computer-readable storage medium” means a non-transitory storage medium. A computer-readable medium may take forms, including, but not limited to, non-volatile media and volatile media. Non-volatile media may include, for example, optical disks, magnetic disks, and so on. Volatile media may include, for example, semiconductor memories, dynamic memory, and so on. Examples of such a computer-readable medium may include, but are not limited to, a floppy disk, a flexible disk, a hard disk, a magnetic tape, other magnetic medium, an ASIC, a graphics processing unit (GPU), a CD, other optical medium, a RAM, a ROM, a memory chip or card, a memory stick, and other media from which a computer, a processor or other electronic device can read. In the context of this document, a computer-readable storage medium may be any tangible medium that can contain or store a program for use by or in connection with an instruction execution system, apparatus, or device.

The following includes definitions of selected terms employed herein. The definitions include various examples and/or forms of components that fall within the scope of a term and that may be used for various implementations. The examples are not intended to be limiting. Both singular and plural forms of terms may be within the definitions.

References to “one embodiment,” “an embodiment,” “one example,” “an example,” and so on indicate that the embodiment(s) or example(s) so described may include a particular feature, structure, characteristic, property, element, or limitation, but that not every embodiment or example necessarily includes that particular feature, structure, characteristic, property, element or limitation. Furthermore, repeated use of the phrase “in one embodiment” does not necessarily refer to the same embodiment, though it may.

“Module,” as used herein, includes a computer or electrical hardware component(s), firmware, a non-transitory computer-readable medium that stores instructions, and/or combinations of these components configured to perform a function(s) or an action(s), and/or to cause a function or action from another logic, method, and/or system. The module may include a microprocessor controlled by an algorithm, a discrete logic (e.g., ASIC), an analog circuit, a digital circuit, a programmed logic device, a memory device including instructions that, when executed, perform an algorithm, and so on. A module, in one or more embodiments, may include one or more CMOS gates, combinations of gates, or other circuit components. Where multiple modules are described, one or more embodiments may include incorporating the multiple modules into one physical module component. Similarly, where a single module is described, one or more embodiments distribute the single module between multiple physical components.

Additionally, a module, as used herein, includes routines, programs, objects, components, data structures, and so on that perform tasks or implement data types. In further aspects, a memory generally stores the noted modules. The memory associated with a module may be a buffer or cache embedded within a processor, a RAM, a ROM, a flash memory, or another suitable electronic storage medium. In still further aspects, a module as envisioned by the present disclosure is implemented as an application-specific integrated circuit (ASIC), a hardware component of a system on a chip (SoC), as a programmable logic array (PLA), as a graphics processing unit (GPU), or as another suitable hardware component that is embedded with a defined configuration set (e.g., instructions) for performing the disclosed functions.

In one or more arrangements, one or more of the modules described herein can include artificial or computational intelligence elements, e.g., neural networks, fuzzy logic, or other machine learning algorithms. Further, in one or more arrangements, one or more of the modules can be distributed among a plurality of the modules described herein. In one or more arrangements, two or more of the modules described herein can be combined into a single module.

Program code embodied on a computer-readable medium may be transmitted using any appropriate medium, including but not limited to wireless, wireline, optical fiber, cable, RF, etc., or any suitable combination of the foregoing. Computer program code for carrying out operations for aspects of the present arrangements may be written in any combination of one or more programming languages, including an object-oriented programming language such as Java™, Smalltalk, C++, or the like, and conventional procedural programming languages, such as the “C” programming language or similar programming languages. The program code may execute entirely on the user's computer, partly on the user's computer, as a stand-alone software package, and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The phrase “at least one of . . . and . . . .” as used herein refers to and encompasses any and all possible combinations of one or more of the associated listed items. As an example, the phrase “at least one of A, B, and C” includes A only, B only, C only, or any combination thereof (e.g., AB, AC, BC, or ABC).

Aspects herein can be embodied in other forms without departing from the spirit or essential attributes thereof. Accordingly, reference should be made to the following claims rather than to the foregoing specification, as indicating the scope hereof.

What is claimed is:

1. A hybrid printed circuit board comprising an optical signal layer embedded within the hybrid printed circuit board that is configured to propagate optical signals from a light source.

2. The hybrid printed circuit board of claim 1, wherein the optical signal layer includes an optical waveguide configured to propagate the optical signals from the light source to a light-sensitive component supported by the hybrid printed circuit board.

3. The hybrid printed circuit board of claim 2, wherein the light-sensitive component is an optically switched gate driver.

4. The hybrid printed circuit board of claim 1, wherein the optical signal layer includes an optical waveguide configured to propagate the optical signals from the light source to a quantum material located within the hybrid printed circuit board.

5. The hybrid printed circuit board of claim 4, further comprising a detector supported by the hybrid printed circuit board and configured to measure a response of the quantum material when excited by the light source and subjected to an external stimulus.

6. The hybrid printed circuit board of claim 5, further comprising embedded Helmholtz coils, wherein the quantum material is located between the embedded Helmholtz coils.

7. The hybrid printed circuit board of claim 6, wherein at least a portion of the embedded Helmholtz coils are constructed using in-plane electrical traces and through-plane electrical vias of the hybrid printed circuit board.

8. The hybrid printed circuit board of claim 6, further comprising a microwave antenna embedded within the hybrid printed circuit board.

9. The hybrid printed circuit board of claim 6, wherein the embedded Helmholtz coils are configured to generate a uniform magnetic field.

10. The hybrid printed circuit board of claim 5, further comprising a component, wherein the response of the quantum material when excited by the light source and subjected to an external stimulus is based on an operating condition of the component.

11. The hybrid printed circuit board of claim 10, wherein a plurality of components are embedded within the hybrid printed circuit board.

12. The hybrid printed circuit board of claim 11, wherein one of the plurality of components is an ultra-wide band gap device.

13. The hybrid printed circuit board of claim 11, further comprising a heat conduction path in thermal communication with one of a plurality of components and a cooling plate.

14. The hybrid printed circuit board of claim 4, wherein the quantum material comprises at least one of nano-diamonds with nitrogen-vacancy centers, hexagonal boron nitride flakes with boron vacancies, and silicon carbide particles containing divacancies or silicon-vacancy defects.

15. The hybrid printed circuit board of claim 4, wherein the light source is a laser diode configured to emit light at a wavelength optimized for a response by the quantum material.

16. The hybrid printed circuit board of claim 4, wherein the quantum material is positioned to monitor specific regions of the hybrid printed circuit board for thermal or mechanical stress.

17. The hybrid printed circuit board of claim 1, wherein the optical signal layer is configured to provide structural support to the hybrid printed circuit board while maintaining optical transmission for signal propagation.

18. The hybrid printed circuit board of claim 1, wherein the optical signal layer is located between electrical signal layers of the hybrid printed circuit board.

19. An optical signal layer having an optical waveguide configured to propagate optical signals from a light source, the optical signal layer is configured to be located between electrical signal layers of a hybrid printed circuit board.

20. The optical signal layer of claim 19, wherein the hybrid printed circuit board includes at least one of a light-sensitive component and a quantum material located within the hybrid printed circuit board, wherein the optical waveguide propagates the optical signals from the light source to at least one of the light-sensitive component and the quantum material located.
